(19) United States
(12) Patent Application Publication
(10) Pub. No.: US 2026/0255493 A1
(43) Pub. Date: Aug. 27, 2026

(54) LAMINATE AND METHOD FOR MANUFACTURING CIRCUIT BOARD

(71) Applicant: Arisawa MFG. Co., Ltd., Niigata (JP)

(72) Inventors: Eiji HIRAIWA, Niigata (JP); Naoki SUZUKI, Niigata (JP); Hiroyuki MATSUYAMA, Niigata (JP); Kenji NAKAMURA, Niigata (JP)

(21) Appl. No.: 19/162,775

(22) PCT Filed: Mar. 7, 2024
(86) PCT No.: PCT/JP2024/008692

§ 371 Date: Sep. 5, 2025

(30) Foreign Application Priority Data
Apr. 5, 2023 (JP) 2023-061292

(51) Int. Cl. H05K 3/02; C22C 9/06; C23C 18/16; C23C 18/50; C23F 17/00; G03F 7/42

(52) U.S. Cl. CPC H05K 3/027; C22C 9/06; C23C 18/1653; C23C 18/50; C23F 17/00; G03F 7/42

(57) ABSTRACT

A laminate (10) includes a film (11), a resin layer (13) including a thermoplastic polyimide resin and being provided on at least one surface of the film, a catalyst layer (15) including palladium and a dispersant covering the palladium and being provided on the resin layer, and an electroless plating layer (17) including nickel and copper and being provided on the catalyst layer. A content of the nickel is 8.0 mass % or more and 13.0 mass % or less with respect to an entire mass of the electroless plating layer (17).

### TECHNICAL FIELD

The present disclosure relates to a laminate and a method for manufacturing a circuit board.

### BACKGROUND ART

Fine wiring is provided on a circuit board that can fix an integrated circuit (IC).

Patent Literature 1 discloses, as a member constituting a circuit board, a laminate including a base material, a plating providing layer laminated on the base material, and a metal plating layer laminated on the plating providing layer. The plating providing layer is constituted from a thermoplastic resin and a plating catalyst.

Patent Literature 2 discloses a laminate including a substrate constituted from glass cloth and a resin, a copper layer provided on the substrate, a first insulating material layer provided on the copper layer, and a seed layer provided on the first insulating material layer. The first insulating material layer is constituted from a thermosetting resin, and a catalyst is adsorbed on a surface. The seed layer is constituted from electroless plating including nickel and copper.

### CITATION LIST

### Patent Literature

Patent Literature 1: International Publication No. WO2020/050338
Patent Literature 2: International Publication No. WO2020/130101

### SUMMARY OF INVENTION

### Technical Problem

The laminate disclosed in Patent Literature 1 has the following problems when fine wiring is provided on the laminate. A resist pattern constituted from a resin is provided on the metal plating layer, and wiring is provided by electrolytic plating. Subsequently, the resist pattern is removed, and the metal plating layer exposed after the removal and the plating providing layer located under the metal plating layer are removed by an acid chemical solution. At this time, the metal plating layer located under the wiring is more likely to be eroded by the chemical solution. Therefore, the laminate disclosed in Patent Literature 1 may be inferior in acid resistance. As a result, reliability of a circuit of the circuit board using the laminate may be inferior.

Further, the laminate disclosed in Patent Literature 2 has the following problems in course of production. The seed layer is provided on the first insulating material layer by electroless plating. In the course, stress is generated in the seed layer. The laminate cannot relax the stress, and peeling between the first insulating material layer and the seed layer is more likely to occur. Therefore, interlayer adhesiveness between the first insulating material layer and the seed layer of the laminate disclosed in Patent Literature 2 may be inferior. As a result, reliability of a circuit of a circuit board using the laminate may be inferior.

The present disclosure has been made in view of the above-described circumstances. In other words, the present disclosure has an objective to provide a laminate having excellent acid resistance and excellent interlayer adhesiveness, and a method for manufacturing a circuit board using the laminate.

### Solution to Problem

The present disclosure is as follows.

[1] A laminate according to the present disclosure includes:
a film;
a resin layer including a thermoplastic polyimide resin and being provided on at least one surface of the film;
a catalyst layer including palladium and a dispersant covering the palladium and being provided on the resin layer; and
an electroless plating layer including nickel and copper and being provided on the catalyst layer,
wherein a content of the nickel is 8.0 mass % or more and 13.0 mass % or less with respect to an entire mass of the electroless plating layer.

[2] The amount of the palladium included in the catalyst layer may be 0.05 mg or more and 0.18 mg or less per 1 dm² in a surface of the resin layer.

[3] The laminate may further include an electrolytic plating layer including copper and being provided on the electroless plating layer.

[4] A method for manufacturing a circuit board according to present disclosure includes:
a resist layer provision process of providing a resist layer on the electroless plating layer constituting the laminate according to aspect [1] above;
an exposure process of exposing the resist layer;
a resist pattern provision process of developing the resist layer exposed in the exposure process, and providing a resist pattern corresponding to wiring planned to be provided;
a wiring layer provision process of providing a wiring layer having conductivity on the electroless plating layer exposed after the resist pattern provision process;
a resist pattern removal process of removing the resist pattern;
a flash etching process of removing the electroless plating layer exposed after the resist pattern removal process; and
a catalyst layer removal process of removing the catalyst layer exposed after the flash etching process.

[5] A method for manufacturing a circuit board according to present disclosure includes:
an electrolytic plating layer provision process of providing an electrolytic plating layer on the electroless plating layer constituting the laminate according to aspect [1] above;
a resist layer provision process of providing a resist layer on the electrolytic plating layer;
an exposure process of exposing the resist layer;
a resist pattern provision process of developing the resist layer exposed in the exposure process, and providing a resist pattern corresponding to wiring planned to be provided;
a wiring layer provision process of providing a wiring layer having conductivity on the electrolytic plating layer exposed after the resist pattern provision process;
a resist pattern removal process of removing the resist pattern;
a flash etching process of removing the electrolytic plating layer exposed after the resist pattern removal process and the electroless plating layer provided under the electrolytic plating layer; and
a catalyst layer removal process of removing the catalyst layer exposed after the flash etching process.

[6] A method for manufacturing a circuit board according to present disclosure includes:
a resist layer provision process of providing a resist layer on the electrolytic plating layer constituting the laminate according to aspect [3] above;
an exposure process of exposing the resist layer;
a resist pattern provision process of developing the resist layer exposed in the exposure process, and providing a resist pattern corresponding to wiring planned to be provided;
a wiring layer provision process of providing a wiring layer having conductivity on the electrolytic plating layer exposed after the resist pattern provision process;
a resist pattern removal process of removing the resist pattern;
a flash etching process of removing the electrolytic plating layer exposed after the resist pattern removal process and the electroless plating layer provided under the electrolytic plating layer; and
a catalyst layer removal process of removing the catalyst layer exposed after the flash etching process.

### Advantageous Effects of Invention

According to the present disclosure, a laminate having excellent acid resistance and excellent interlayer adhesiveness, and a method for manufacturing a circuit board using the laminate can be provided.

### BRIEF DESCRIPTION OF DRAWINGS

FIG. 1 is a schematic cross-sectional view of a laminate according to an embodiment; and

FIG. 2 is a schematic cross-sectional view of the laminate according to the embodiment.

### DESCRIPTION OF EMBODIMENTS

A laminate and a method for manufacturing a circuit board according to an embodiment for implementing the present disclosure (hereinafter referred to as an embodiment) are described below in detail. The embodiment below is an example for describing the present disclosure, and does not intend to limit the present disclosure to the following content. The present disclosure can be implemented while modifications are appropriately made within the scope of the purpose of the present disclosure.

### Laminate 10

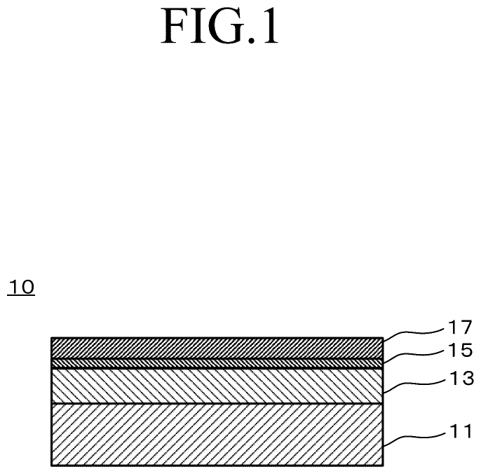

As illustrated in FIG. 1, a laminate 10 according to the embodiment includes a film 11, a resin layer 13 including a thermoplastic polyimide resin and being provided on at least one surface of the film 11, a catalyst layer 15 including palladium and a dispersant covering the palladium and being provided on the resin layer 13, and an electroless plating layer 17 including nickel and copper and being provided on the catalyst layer 15.

The laminate 10 has the configuration described above, and thus has excellent acid resistance and excellent interlayer adhesiveness. Reliability of a circuit of a circuit board using such a laminate 10 is increased. Hereinafter, the film 11, the resin layer 13, the catalyst layer 15, and the electroless plating layer 17 constituting the laminate 10 are each described.

### Film 11

The film 11 is preferably a film having dimensional stability, heat resistance, a dielectric characteristic, and the like. Examples of a resin constituting the film having the characteristics include, for example, thermosetting polyimide, polyamide-imide, a liquid crystal polymer, polyphenylene sulfide, syndiotactic polystyrene, polyethylene terephthalate, polyethylene naphthalate, polycarbonate, polybutylene terephthalate, polyether ether ketone, polyether sulfone, polyphenylene ether, a fluorine resin, and the like.

Among the resins described above, thermosetting polyimide having excellent heat resistance and excellent dimensional stability, a liquid crystal polymer and a fluorine resin having an excellent dielectric characteristic are preferable. These resins are also preferable from a viewpoint of excellent processability. The resin constituting the film 11 may be constituted from one kind of a resin, or may be constituted from two or more kinds of resins.

A thickness of the film 11 is, for example, preferably 5 μm or more and 100 μm or less, more preferably 7.5 μm or more and 100 μm or less, and further preferably 10 μm or more and 50 μm or less from a viewpoint of relaxing stress generated when the electroless plating layer 17 is provided in the laminate 10 and a viewpoint of improving processability.

A tensile modulus of elasticity of the film 11 is, for example, preferably 2 GPa or more and 10 GPa or less, and more preferably 3 GPa or more and 8 GPa or less from a viewpoint of relaxing stress generated when the electroless plating layer 17 is provided and a viewpoint of improving processability. In this way, stress generated when the electroless plating layer 17 is provided is relaxed, and peeling between layers being the catalyst layer 15 and the electroless plating layer 17 is suppressed. In other words, the laminate 10 having excellent interlayer adhesiveness is acquired. A tensile modulus of elasticity of the film 11 can be measured by a measurement method in conformity with JIS K7161.

### Resin Layer 13

A resin constituting the resin layer 13 includes a thermoplastic polyimide resin. The resin layer 13 includes the thermoplastic polyimide resin, and thus interlayer adhesiveness between the resin layer 13 and the film 11 improves. The thermoplastic polyimide resin has a high affinity for the dispersant included in the catalyst layer 15, and thus interlayer adhesiveness between the resin layer 13 and the catalyst layer 15 improves. The amount of the thermoplastic polyimide resin included in the resin layer 13 is, for example, 1 mass % or more and 100 mass % or less, preferably 20 mass % or more and 100 mass % or less, and more preferably 40 mass % or more and 100 mass % or less with respect to mass of the entire resin layer 13. Note that the amount of the thermoplastic polyimide resin included in the resin layer 13 represents the amount of only the thermoplastic polyimide resin except for volatile components such as an organic solvent.

The thermoplastic polyimide resin included in the resin layer 13 is constituted from, for example, condensation polyimide. The condensation polyimide is acquired by copolymerizing acid dianhydride and diamine.

The acid dianhydride may be acid dianhydride that has a condensation reaction to the diamine. Examples of the acid dianhydride include, for example, 3,4,3′4′-biphenyltetracarboxylic acid dianhydride, 2,3,3′,4′-biphenyltetracarboxylic acid dianhydride, 2,3,2′,3′-biphenyltetracarboxylic acid dianhydride, pyromellitic acid dianhydride, 2,3,6,7-naphthalenetetracarboxylic acid dianhydride, 1,2,5,6-naphthalenetetracarboxylic acid dianhydride, 3,3′,4,4′-benzophenonetetracarboxylic acid dianhydride, 4,4′-oxydiphthalic acid dianhydride, 2,2-bis(3,4-dicarboxyphenyl)propane dianhydride, 3,4,9,10-perylenetetracarboxylic acid dianhydride, bis(3,4-dicarboxyphenyl)propane dianhydride, 1,1-bis(2,3-dicarboxyphenyl)ethane dianhydride, 1,1-bis(3,4-dicarboxyphenyl)ethane dianhydride, bis(2,3-dicarboxyphenyl) methane dianhydride, bis(3,4-dicarboxyphenyl)ethane dianhydride, bis(3,4-dicarboxyphenyl) sulfone dianhydride, p-phenylenebis(trimellitic acid monoester anhydride), ethylenebis(trimellitic acid monoester anhydride), bisphenol A bis(trimellitic acid monoester anhydride), and the like.

The diamine may be diamine that has a condensation reaction to the acid dianhydride. Examples of the diamine include, for example, p-phenylenediamine, m-phenylenediamine, 2,4-diaminotoluene, 4,4′-diaminobiphenyl, 4,4′-diamino-2,2′-bis(trifluoromethyl)biphenyl, 3,3′-diaminodiphenyl sulfone, 4,4′-diaminodiphenyl sulfone, 4,4′-diaminodiphenyl sulfide, 4,4′-diaminodiphenyl methane, 4,4′-diaminodiphenyl ether, 3,4′-diaminodiphenyl ether, 3,3′-diaminodiphenyl ether, 4,4′-bis(4-aminophenoxy)biphenyl, bis[4-(4-aminophenoxy)phenyl]sulfone, bis[4-(3-aminophenoxy)phenyl]sulfone, 2,2-bis[4-(4-aminophenoxy)phenyl]propane, 2,2-bis[4-(4-aminophenoxy)phenyl]hexafluoropropane, 1,3-bis[2-(4-aminophenyl)-2-propyl]benzene, 1,4-bis[2-(4-aminophenyl)-2-propyl]benzene, 2,2′-dimethyl-4,4′-diaminobiphenyl, 2,2′-bis(trifluoromethyl)benzidine, 2,2-bis(4-aminophenoxyphenyl) isopropane, 1,3-bis(4-aminophenoxy)benzene, 1,4-bis(4-aminophenoxy)benzene, 1,3-bis(3-aminophenoxy)benzene, and the like.

In the thermoplastic polyimide resin included in the resin layer 13, a value of a storage elastic modulus at 300° C. is preferably less than 20% of a value of a storage elastic modulus at 30° C. from a viewpoint of improving interlayer adhesiveness between the resin layer 13 and the catalyst layer 15. A storage elastic modulus can be measured by a dynamic viscoelasticity measurement method.

A tensile modulus of elasticity of the resin layer 13 is preferably 5 GPa or less, for example. A tensile modulus of elasticity of the resin layer 13 is 5 GPa or less, and thus stress generated when the electroless plating layer 17 is provided on the catalyst layer 15 described below is relaxed by the resin layer 13, and interlayer peeling between the catalyst layer 15 and the electroless plating layer 17 is suppressed. A tensile modulus of elasticity of the resin layer 13 can be measured in conformity with JIS K7161.

The resin layer 13 is provided on at least one surface of the film 11. A thickness of the resin layer 13 may be able to improve adhesive strength between the resin layer 13 and the catalyst layer 15, and is, for example, 0.01 μm or more and 10.0 μm or less, and preferably 0.02 μm or more and 1.0 μm or less.

### Catalyst Layer 15

The catalyst layer 15 is laminated on the resin layer 13. The catalyst layer 15 includes palladium bonded to copper included in the electroless plating layer 17, and a dispersant covering the palladium. The electroless plating layer 17 is provided by using the palladium as a foundation. In this way, interlayer adhesiveness between the electroless plating layer 17 and the catalyst layer 15 improves. The amount of the palladium included in the catalyst layer 15 is, for example, 0.05 mg or more and 0.18 mg or less, preferably 0.08 mg or more and 0.18 mg or less, and more preferably 0.10 mg or more and 0.16 mg or less per unit area 1 dm² in a surface of the resin layer 13.

The dispersant covering the palladium is constituted from a compound that can be bonded to the palladium, and is, for example, a nitrogen-containing compound including nitrogen in an end functional group and/or a compound having an unsaturated bond. A bond between the palladium and the compound is, for example, a coordinate bond, an ion bond, and a covalent bond. Examples of the nitrogen-containing compound include, for example, a polymer having an ammonium group as an end functional group. Examples of the compound having the unsaturated bond include, for example, acrylic acid polyethylene glycol alkyl ether, and the like. The dispersant is preferably the nitrogen-containing compound, more specifically, the polymer having the ammonium group as the end functional group from a viewpoint of improving interlayer adhesiveness between the catalyst layer 15 and the resin layer 13.

### Electroless Plating Layer 17

The electroless plating layer 17 includes nickel and copper, and is laminated on the catalyst layer 15. A content of the nickel is 8.0 mass % or more and 13.0 mass % or less with respect to an entire mass of the electroless plating layer 17. The electroless plating layer 17 including the above-described amount of the nickel has a lot of the nickel in a boundary surface of the electroless plating layer 17 in contact with the catalyst layer 15. In other words, the copper is little in the boundary surface of the electroless plating layer 17 in contact with the catalyst layer 15, and thus the electroless plating layer 17 is less likely to be eroded even when an acid chemical solution enters an interface between the catalyst layer 15 and the electroless plating layer 17. Therefore, acid resistance of the laminate 10 constituted from the electroless plating layer 17 including the above-described amount of the nickel improves. Furthermore, a content of the nickel is the above-described content, and thus the electroless plating layer 17 that needs to be removed in a flash etching process described below can be reliably removed. A content of the nickel can be obtained by inductively coupled plasma (ICP)-atomic emission spectroscopy.

A thickness of the electroless plating layer 17 may be able to allow uniform electroless plating layer 17 to be provided on the catalyst layer 15, and is, for example, preferably 0.05 μm or more and 2.0 μm or less, and more preferably 0.10 μm or more and 2.0 μm or less.

The above-described laminate 10 constituted from the film 11, the resin layer 13, the catalyst layer 15, and the electroless plating layer 17 has excellent acid resistance and excellent interlayer adhesiveness. Therefore, reliability of a circuit of a circuit board using the laminate 10 is increased.

Note that, for the film 11 described above, a gas barrier layer that suppresses transmission of oxygen may be provided on at least one surface of the film 11 from a viewpoint of reducing entry of oxygen into the laminate 10. The gas barrier layer is provided on the film 11, and thus entry of oxygen into the laminate 10 can be suppressed. Even when the laminate 10 constituted from such a film 11 is exposed under, for example, a high-temperature atmosphere at 150° C. for 400 hours or longer, entry of oxygen is little, and thus oxidation of the electroless plating layer 17 is suppressed. In this way, interlayer adhesiveness between the catalyst layer 15 and the electroless plating layer 17 improves. Furthermore, transmission of oxygen via such a film 11 is little, and thus deterioration of the resin layer by oxygen is suppressed, and interlayer adhesiveness between the film 11 and the resin layer 13 improves.

Furthermore, the electroless plating layer 17 in which oxidation is suppressed has erosion resistance to an acid chemical solution. In this way, for example, even when an acid chemical solution enters the interface between the catalyst layer 15 and the electroless plating layer 17, the electroless plating layer 17 is less likely to be eroded. Acid resistance of the laminate 10 constituted from such a film 11 improves.

The gas barrier layer described above is constituted from, for example, silicon dioxide, zinc oxide, and the like. A thickness of the gas barrier layer is, for example, preferably 10 nm or more and 100 nm or less.

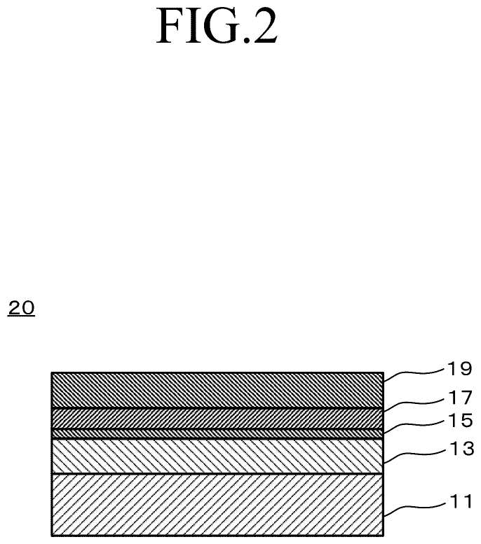

An electrolytic plating layer 19 may be further provided on the electroless plating layer 17 of the laminate 10. In other words, as illustrated in FIG. 2, a laminate 20 according to the embodiment includes the film 11, the resin layer 13 provided on at least one surface of the film 11, the catalyst layer 15 provided on the resin layer 13, the electroless plating layer 17 provided on the catalyst layer 15, and the electrolytic plating layer 19 provided on the electroless plating layer 17.

Since the laminate 20 includes, on a surface of the laminate, the electrolytic plating layer 19 having more excellent conductivity than the electroless plating layer 17, surface resistivity of the surface can be reduced to, for example, 0.1Ω/□. When a circuit board is manufactured, a wiring layer having conductivity can be provided on the electrolytic plating layer 19 in a short time. The electrolytic plating layer 19 preferably includes copper from a viewpoint of interlayer adhesiveness to the electroless plating layer 17. A thickness of the electrolytic plating layer 19 is, for example, preferably 0.1 μm or more and 35.0 μm or less, and more preferably 0.2 μm or more and 18.0 μm or less from a viewpoint of making it easier to provide the wiring layer. Note that the film, the resin layer, the catalyst layer, and the electroless plating layer constituting the laminate 20 are the same as the film and each of the layers constituting the laminate 10, and are thus provided with the same reference signs as the reference signs provided to the laminate 10.

Method for Manufacturing Laminate 10 in which Resin Layer 13, Catalyst Layer 15, and Electroless Plating Layer 17 are Provided in This Order on One Surface of

### Film 11

The laminate 10 in which the resin layer 13, the catalyst layer 15, and the electroless plating layer 17 are provided in this order on one surface of the film 11 can be manufactured by, for example, the following manufacturing method.

First, a resin composite including polyamic acid being a precursor of a thermoplastic polyimide resin is applied to one surface of the film 11, heating is performed at 60° C. or higher and 120° C. or lower for 1 minute or longer and 30 minutes or shorter, and the resin layer 13 is provided. A catalytic solution including palladium and a dispersant is applied onto the resin layer 13, heating is performed at 80° C. or higher and 150° C. or lower for 1 minute or longer and 60 minutes or shorter, and the catalyst layer 15 is provided. Subsequently, in order to acquire the thermoplastic polyimide resin by performing imidization on the polyamic acid included in the resin composite, the laminate 10 in which the resin layer 13 and the catalyst layer 15 are provided in this order on one surface of the film 11 is heated at 200° C. or higher and 300° C. or lower for 1 minute or longer and 30 minutes or shorter.

Next, the laminate 10 is immersed in a plating solution including nickel and copper and having pH kept to be 7 or more and 10 or less for 30 seconds or longer and 30 minutes or shorter, and the electroless plating layer 17 is provided on the catalyst layer 15. Subsequently, heating treatment (annealing) is performed on the laminate 10 under a nitrogen atmosphere at 120° C. or higher and 350° C. or lower for 1 minute or longer and 60 minutes or shorter, and the laminate 10 in which the resin layer 13, the catalyst layer 15, and the electroless plating layer 17 are provided in this order on one surface of the film 11 is acquired.

A usable plating solution may be able to provide the electroless plating layer 17, and examples of the usable plating solution include, for example, an electroless nickel plating solution and the like. One example is an OPC ALOCOPPER solution made by OKUNO Chemical Industries Co., Ltd. A concentration of the nickel included in the plating solution is, for example, 0.10 g/L or more and 0.40 g/L or less, and a concentration of the copper is, for example, 2.0 g/L or more and 4.0 g/L or less.

Note that the laminate 10 acquired as described above may be immersed in an electrolytic plating solution including copper and subjected to electrolytic plating treatment at 0.05 A/dm² or more and 10.0 A/dm² or less for 1 minute or longer and 60 minutes or shorter, and the laminate 20 in which the electrolytic plating layer 19 may be further provided on the electroless plating layer 17 may be acquired. Examples of a usable electrolytic plating solution include, for example, an electrolytic plating solution containing copper sulfate, an electrolytic copper plating solution containing copper pyrophosphate, an electrolytic copper plating solution containing copper cyanide, and the like. One example is a top lucina SF solution made by OKUNO Chemical Industries Co., Ltd. A concentration of copper sulfate pentahydrate included in the solution is, for example, 60 g/L or more and 110 g/L or less.

Method for Manufacturing Laminate in which Resin Layer 13, Catalyst Layer 15, and Electroless Plating Layer 17 are Provided in This Order on Both Surfaces of Film 11

A laminate in which the resin layer 13, the catalyst layer 15, and the electroless plating layer 17 are provided in this order on both surfaces of the film 11 can be manufactured by, for example, the following manufacturing method. First, a resin composite including polyamic acid being a precursor of a thermoplastic polyimide resin is applied to both surfaces of the film, heating is performed at 60° C. or higher and 250° C. or lower for 1 minute or longer and 30 minutes or shorter, and the resin layer 13 is provided on each of both surfaces of the film 11. A catalytic solution including palladium and a dispersant is applied onto the resin layers 13, heating is performed at 80° C. or higher and 150° C. or lower for 1 minute or longer and 60 minutes or shorter, and the catalyst layer 15 is provided on each of the resin layers 13. Subsequently, in order to acquire the thermoplastic polyimide resin by performing imidization on the polyamic acid included in the resin composite, the laminate in which the resin layer 13 and the catalyst layer 15 are provided in this order on both surfaces of the film 11 is heated at 200° C. or higher and 300° C. or lower for 1 minute or longer and 30 minutes or shorter.

Next, the laminate is immersed in a plating solution including nickel and copper and having pH kept to be 7 or more and 10 or less for 30 seconds or longer and 30 minutes or shorter, and the electroless plating layer 17 is provided on the catalyst layer 15. Subsequently, heating treatment is performed on the laminate under a nitrogen atmosphere at 120° C. or higher and 350° C. or lower for 1 minute or longer and 60 minutes or shorter, and the laminate in which the resin layer 13, the catalyst layer 15, and the electroless plating layer 17 are provided in this order on both surfaces of the film 11 is acquired.

Examples of a plating solution that can be used in the manufacturing method include the same plating solution as the plating solution used in the method for manufacturing the laminate 10 in which the resin layer 13, the catalyst layer 15, and the electroless plating layer 17 are provided in this order on one surface of the film 11.

Note that the laminate acquired as described above may be immersed in an electrolytic plating solution including copper and subjected to electrolytic plating treatment at 0.05 A/dm² or more and 10.0 A/dm² or less for 1 minute or longer and 60 minutes or shorter, and thus the laminate in which the electrolytic plating layer 19 may be further provided on the electroless plating layer 17 may be acquired. Examples of a usable electrolytic plating solution include, for example, an electrolytic plating solution containing copper sulfate, an electrolytic copper plating solution containing copper pyrophosphate, an electrolytic copper plating solution containing copper cyanide, and the like. One example is a top lucina SF solution made by OKUNO Chemical Industries Co., Ltd. A concentration of copper sulfate pentahydrate included in the solution is, for example, 60 g/L or more and 110 g/L or less.

In the process of providing the catalyst layer 15 in the method for manufacturing the two laminates described above, examples of a usable catalytic solution include, for example, a catalytic solution including a dispersant, palladium covered with the dispersant, and a solvent. The dispersant is constituted from a compound that can be bonded to the palladium, and examples of the dispersant include, for example, a nitrogen-containing compound including nitrogen in an end functional group and/or a compound having an unsaturated bond. A bond between the palladium and the compound is, for example, a coordinate bond, an ion bond, and a covalent bond, and the coordinate bond is preferable from a viewpoint of dispersibility. Examples of the nitrogen-containing compound include, for example, a polymer having an ammonium group as an end functional group. Examples of the compound having the unsaturated bond include, for example, acrylic acid polyethylene glycol alkyl ether, and the like. A content of the dispersant included in the catalytic solution is, for example, 0.1 mass % or more and 90 mass % or less, preferably 0.2 mass % or more and 50 mass % or less, and more preferably 0.3 mass % or more and 30 mass % or less with respect to mass of the entire catalytic solution. By using such a catalytic solution, the palladium can be caused to uniformly adhere to a surface of the resin layer.

### Method for Manufacturing Circuit Board

A method for manufacturing a circuit board using the laminate 10 is described by taking, as an example, the laminate 10 in which the resin layer 13, the catalyst layer 15, and the electroless plating layer 17 are provided in this order on one surface of the film 11.

The method for manufacturing a circuit board includes a resist layer provision process, an exposure process, a resist pattern provision process, a wiring layer provision process, a resist pattern removal process, a flash etching process, and a catalyst layer removal process.

### Resist Layer Provision Process

A resist layer for providing a resist pattern is provided on an electroless plating layer. A resist material constituting the resist layer may be a material that can provide a resist pattern by development after exposure, and examples of the resist material include a positive resist material and a negative resist material. The positive resist material is dissolved in a developing solution by application of light, and is not dissolved in the developing solution without application of light. Examples of an aspect of the positive resist material include, for example, a positive resist solution, and a positive dry film. The negative resist material is not dissolved in a developing solution by application of light, and is dissolved in the developing solution without application of light. Examples of an aspect of the negative resist material include, for example, a negative resist solution, and a negative dry film.

In the resist layer provision process, the resist layer may be provided by using the positive resist material, or the resist layer may be provided by using the negative resist material.

The resist layer provision process according to the present embodiment is described by taking, as an example, a process of providing the resist layer using the negative dry film. The negative dry film is laminated on the electroless plating layer, heated, and pressurized. A condition for heating and pressurization may be a condition that the electroless plating layer and the negative dry film can adhere closely to each other, and, when a vacuum laminator is used, for example, the condition is 30° C. or higher and 100° C. or lower, 0.1 MPa or more and 1.0 MPa or less, and 5 seconds or longer and 60 seconds or shorter. In this way, the resist layer is provided on the electroless plating layer. Heating and pressurization may be performed under a decompressed atmosphere.

Note that, when the negative resist solution is used, the negative resist solution may be applied onto the electroless plating layer and heated. In this way, the resist layer constituted from the negative resist solution is provided on the electroless plating layer.

### Exposure Process

In order to provide the resist pattern, the resist layer is exposed via a photomask. The photomask used in this process is a photomask corresponding to wiring planned to be provided, and includes, for example, a light-shielding region that shields light and is provided in a desired shape of a circuit, and an opening region that passes light. A wavelength of light used for exposure may be a wavelength with which a fine pattern can be provided, and is, for example, 200 nm or more and 500 nm or less. An exposure condition may be a condition that a fine pattern can be provided, and is, for example, a condition that a high pressure mercy lamp is used and an accumulated light amount is 50 mJ/cm² or more and 1,500 mJ/cm² or less.

### Resist Pattern Provision Process

The exposed resist layer is developed. When the resist layer is exposed and developed via the photomask, only a portion of the resist layer without application of light is dissolved in the developing solution, and the electroless plating layer located directly under the dissolved resist layer is exposed. The resist pattern is provided on the resist layer by the exposure and the development. In the wiring layer provision process being the next process, a wiring layer having conductivity is provided by, for example, performing electrolytic plating on a laminate on which the resist pattern is provided.

Note that a developing solution used for the development may be able to develop the exposed resist layer, and examples of the developing solution include, for example, an aqueous solution with alkalinity such as a sodium carbonate aqueous solution. The resist pattern according to the present embodiment is a resist layer provided in a shape corresponding to an outline of the opening region of the photomask by exposure and development.

### Wiring Layer Provision Process

The wiring layer having conductivity is provided on the exposed electroless plating layer 17. The wiring layer can be provided by, for example, electrolytic plating. A method for performing electrolytic plating may be a method that can provide the wiring layer on the electroless plating layer. For example, a device that can pass a current through an electrolytic plating solution including copper and the laminate 10, and perform plating on the laminate 10 is prepared. Next, examples include a method for immersing the laminate 10 in the electrolytic plating solution, and performing electrolytic plating treatment at 0.05 A/dm² or more and 10.0 A/dm² or less for 1 minute or longer and 60 minutes or shorter. Examples of the electrolytic plating solution including the copper and being used at this time include, for example, a copper sulfate plating solution, a copper pyrophosphate plating solution, and a copper cyanide plating solution. One example is a top lucina SF solution made by OKUNO Chemical Industries Co., Ltd. A concentration of copper sulfate pentahydrate included in the solution is 60 g/L or more and 110 g/L or less.

### Resist Pattern Removal Process

The resist pattern is removed after the wiring layer is provided in the wiring layer provision process. A solvent used for removing the resist pattern may be a solvent that can remove the resist material constituting the resist pattern, and examples of the solvent include, for example, an organic amine solvent, a ketone solvent, an alkaline solvent, and the like.

### Flash Etching Process

The electroless plating layer 17 exposed by removing the resist pattern is removed. An etching solution used for removing the exposed electroless plating layer 17 may be an etching solution that can remove the electroless plating layer 17 including the nickel and the copper, and examples of the etching solution include, for example, a sulfuric acid-hydrogen peroxide etching solution, a sodium persulfate etching solution, a ferric chloride etching solution, a cupric chloride etching solution, and the like. Note that the wiring layer is thicker than the electroless plating layer 17, and thus the flash etching process has a small influence on the wiring layer.

### Catalyst Layer Removal Process

The catalyst layer 15 exposed by removing the electroless plating layer 17 is removed. A chemical solution used for removing the exposed catalyst layer 15 may be a chemical solution that can remove the catalyst layer 15 including palladium, and examples of the chemical solution include, for example, a hydrochloric acid chemical solution, a nitric acid chemical solution, a permanganate chemical solution, and the like.

A circuit board can be acquired through the processes described above.

### Method for Manufacturing Circuit Board Including Electrolytic Plating Layer Provision Process

Next, a method for manufacturing a circuit board including an electrolytic plating layer provision process is described by taking, as an example, the laminate 10 also used in the above-described method for manufacturing a circuit board, that is, the laminate 10 in which the resin layer 13, the catalyst layer 15, and the electroless plating layer 17 are provided in this order on one surface of the film 11.

The method for manufacturing a circuit board includes an electrolytic plating layer provision process, a resist layer provision process, an exposure process, a resist pattern provision process, a wiring layer provision process, a resist pattern removal process, a flash etching process, and a catalyst layer removal process. Hereinafter, the method for manufacturing a circuit board including the electrolytic plating layer provision process is different from the above-described method for manufacturing a circuit board in a point in which the electrolytic plating layer provision process is included before the resist layer provision process. Hereinafter, the electrolytic plating layer provision process is described in detail, and only a brief summary of the other processes is described.

### Electrolytic Plating Layer Provision Process

The electrolytic plating layer 19 is provided on the electroless plating layer 17 of the laminate 10 in which the resin layer 13, the catalyst layer 15, and the electroless plating layer 17 are provided in this order on one surface of the film 11. A method for performing electrolytic plating may be a method that can provide the electrolytic plating layer 19 on the electroless plating layer 17 of the laminate 10. For example, a device that can pass a current through an electrolytic plating solution including copper and the laminate 10, and perform plating on the electroless plating layer 17 of the laminate 10 is prepared. Next, examples include a condition for immersing the laminate 10 in the electrolytic plating solution, and performing electrolytic plating treatment at 0.05 A/dm² or more and 10.0 A/dm² or less for 1 minute or longer and 60 minutes or shorter.

Examples of the electrolytic plating solution including the copper and being used at this time include, for example, a copper sulfate plating solution, a copper pyrophosphate plating solution, and a copper cyanide plating solution. A concentration of the copper included in the electrolytic plating solution is, for example, 10 g/L or more and 110 g/L or less. One example is a top lucina SF solution made by OKUNO Chemical Industries Co., Ltd. A concentration of copper sulfate pentahydrate included in the solution is 60 g/L or more and 110 g/L or less. The electrolytic plating layer 19 is further laminated on the electroless plating layer 17 in this process, and thus the electrolytic plating layer 19 having more excellent conductivity than the electroless plating layer 17 is provided on a surface of the laminate. In this way, surface resistivity of the laminate surface can be reduced to, for example, 0.1Ω/□. The surface resistivity is reduced to, for example, 0.1Ω/□, and thus the wiring layer having conductivity is more likely to be finely provided on the electrolytic plating layer 19. The surface resistivity can be measured in conformity with JIS K7194.

### Resist Layer Provision Process

A resist layer for providing a resist pattern corresponding to wiring planned to be provided is provided on the electrolytic plating layer 19. In the resist layer provision process, the resist layer may be provided by using a positive resist material, or the resist layer may be provided by using a negative resist material. The resist layer provision process according to the present embodiment is described by taking, as an example, a process of providing the resist layer using the negative resist material of a dry film type. The dry film is laminated on the electrolytic plating layer 19, heated, and pressurized. A condition for heating and pressurization may be a condition that the electrolytic plating layer 19 and the dry film can adhere closely to each other, and, when a vacuum laminator is used, for example, the condition is 30° C. or higher and 100° C. or lower, 0.1 MPa or more and 1.0 MPa or less, and 5 seconds or longer and 60 seconds or shorter. In this way, the resist layer is provided on the electrolytic plating layer 19. Heating and pressurization may be performed under a decompressed atmosphere.

Note that, when a resist solution is used as an aspect of the resist material, the resist solution may be applied onto the electrolytic plating layer 19 and heated. In this way, the resist layer constituted from the resist solution is provided on the electrolytic plating layer 19.

### Exposure Process

In order to provide the resist pattern, the resist layer is exposed via a photomask.

### Resist Pattern Provision Process

The exposed resist layer is developed. In this way, the resist pattern corresponding to the wiring planned to be provided is provided on the electrolytic plating layer 19.

### Wiring Layer Provision Process

A wiring layer having conductivity is provided on the exposed electrolytic plating layer 19 by performing electrolytic plating on the laminate 10 on which the resist pattern is provided.

### Resist Pattern Removal Process

The resist pattern is removed.

### Flash Etching Process

The electrolytic plating layer 19 exposed by removing the resist pattern and the electroless plating layer 17 provided under the electrolytic plating layer 19 are removed. An etching solution used for removing the layers may be an etching solution that can remove the electrolytic plating layer 19 including copper and the electroless plating layer 17 including nickel and copper, and examples of the etching solution include, for example, a sulfuric acid-hydrogen peroxide etching solution, a sodium persulfate etching solution, a ferric chloride etching solution, a cupric chloride etching solution, and the like.

### Catalyst Layer Removal Process

The catalyst layer 15 exposed by removing the electroless plating layer 17 is removed.

As described above, a circuit board can be acquired from the method for manufacturing a circuit board including the electrolytic plating layer provision process.

Method for Manufacturing Circuit Board Using Laminate 20 in which Electrolytic Plating Layer 19 is Provided on Electroless Plating Layer 17

A method for manufacturing a circuit board using the laminate 20 is described by taking, as an example, the laminate 20 in which the electrolytic plating layer 19 is provided on the electroless plating layer 17, that is, the laminate 20 in which the resin layer 13, the catalyst layer 15, the electroless plating layer 17, and the electrolytic plating layer 19 are provided in this order on one surface of the film 11.

The method for manufacturing a circuit board includes a resist layer provision process, an exposure process, a resist pattern provision process, a wiring layer provision process, a resist pattern removal process, a flash etching process, and a catalyst layer removal process. Hereinafter, the method for manufacturing a circuit board using the laminate 20 in which the electrolytic plating layer 19 is further provided on the electroless plating layer 17 includes substantially the same processes as those of the above-described method for manufacturing a circuit board, and thus only a brief summary is described.

### Resist Layer Provision Process

A resist layer for providing a resist pattern is provided on the electrolytic plating layer 19.

### Exposure Process

In order to provide the resist pattern, the resist layer is exposed via a photomask.

### Resist Pattern Provision Process

The exposed resist layer is developed. In this way, the resist pattern corresponding to the wiring planned to be provided is provided on the electrolytic plating layer 19.

### Wiring Layer Provision Process

A wiring layer having conductivity is provided on the exposed electrolytic plating layer 19 by performing electrolytic plating on the laminate 20 on which the resist pattern is provided.

### Resist Pattern Removal Process

The resist pattern is removed.

### Flash Etching Process

The electrolytic plating layer 19 exposed by removing the resist pattern and the electroless plating layer 17 provided under the electrolytic plating layer 19 are removed.

### Catalyst Layer Removal Process

The catalyst layer 15 exposed by removing the electroless plating layer 17 is removed.

As described above, a circuit board can be acquired from the method for manufacturing a circuit board using the laminate 20 in which the electrolytic plating layer 19 is further provided on the electroless plating layer 17.

As described above, the method for manufacturing a circuit board according to the present embodiment is described by taking, as examples, the laminate 10 in which the resin layer 13, the catalyst layer 15, and the electroless plating layer 17 are provided in this order on one surface of the film 11, and the laminate 20 in which the electrolytic plating layer 19 is further provided on the electroless plating layer 17.

Note that the present disclosure is not limited to the laminates, and a laminate in which the resin layer 13, the catalyst layer 15, and the electroless plating layer 17 are provided in this order on each of both surfaces of the film 11, or a laminate in which the resin layer 13, the catalyst layer 15, the electroless plating layer 17, and the electrolytic plating layer 19 are provided in this order on each of both surfaces of the film can also be used. Further, in the method for manufacturing a circuit board according to the present embodiment, various photoetching processes can be appropriately selected.

### EXAMPLES

The present disclosure is described in more detail by examples below. The present disclosure is not limited in any way by the examples below.

### Example 1

### Production of Laminate

### (1) Production of Resin Layer 13

### (1-1) Preparation of Polyamic Acid Solution

85 g of N,N-dimethylacetamide (DMAc made by MITSUBISHI GAS CHEMICAL COMPANY, INC.), 1.034 g (0.003 mol) of 2,2-bis[4-(4-aminophenoxy)phenyl]propane (BAPP made by Wakayama Seika Kogyo Co., Ltd.), and 6.628 g (0.023 mol) of 1,3-bis(4-aminophenoxy)benzene (TPE-R made by Wakayama Seika Kogyo Co., Ltd.) were added into a reaction container and stirred at a room temperature, and BAPP and TPE-R were dissolved in DMAc. 7.338 g (0.025 mol) of 3,4,3′,4′-biphenyltetracarboxylic dianhydride (BPDA made by UBE Corporation) were gradually added to the acquired solution and stirred for 3 hours at a room temperature, and a resin composite including polyamic acid was acquired. The polyamide acid solution was acquired by dilution with DMAc in such a way that a solid concentration of the acquired resin composite was 2 mass %.

### (1-2) Provision of Resin Layer 13

As the film 11, the polyamic acid solution acquired by preparation in advance was applied to one surface of a polyimide film (Kapton (registered trademark) 100EN-C made by DU PONT-TORAY CO., LTD.) having a thickness of 25 μm by a bar coater in such a way that a thickness after heating was 100 nm. After application, heating was performed at 120° C. for 5 minutes, and a laminate in which the resin layer 13 was provided on one surface of the polyimide film was acquired.

### (2) Production of Catalyst Layer 15

A catalytic solution (CP-018 made by Nissan Chemical Corporation) including 0.45 mass % of palladium was applied by the bar coater onto the resin layer 13 of the laminate acquired in (1-2). After application, heating was performed at 120° C. for 10 minutes, and a laminate in which the catalyst layer 15 was provided on the resin layer 13 was acquired. The laminate was further heated at 240° C. for 15 minutes. Note that it was confirmed that 0.15 mg of the palladium adhered to the surface of the resin layer 13 of the acquired laminate per unit area 1 dm². An adhesion amount of the palladium was measured by ICP atomic emission spectroscopy. A device used for the measurement was an ICPE-9800 series made by SHIMADZU CORPORATION.

### (3) Production of Electroless Plating Layer 17

As an electroless plating solution used for laminating the electroless plating layer 17 on the catalyst layer 15, OPC ALOCOPPER (initial copper concentration of 3.16 g/L, nickel concentration of 0.14 g/L, and sodium hypophosphite concentration of 24 g/L) made by OKUNO Chemical Industries Co., Ltd. was prepared, sodium hydroxide was added to the plating solution, and the electroless plating solution having pH 9.0 was prepared. After the electroless plating solution was put in a plating bathtub, a solution temperature was set to 50° C. The laminate acquired in (2) was immersed in the plating bathtub for 10 minutes. Subsequently, the laminate was raised, washed with water, and dried, and heating treatment was performed at 300° C. for 5 minutes under a nitrogen atmosphere. After cooling, the laminate 10 in which the electroless plating layer 17 was provided on the catalyst layer 15 was acquired. An adhesion property was evaluated by using the acquired laminate 10.

A thickness of the electroless plating layer 17 of the acquired laminate 10 was 0.15 μm. The thickness of the electroless plating layer 17 was measured by ICP atomic emission spectroscopy. A device used for the measurement was an ICPE-9800 series made by SHIMADZU CORPORATION.

A content of nickel of the electroless plating layer 17 was 8.0 mass %. The content of the nickel was obtained as follows. First, the laminate 10 being cut into a square of 50 mm×50 mm and provided with the electroless plating layer 17 was prepared. Next, 15 mL of an aqueous solution acquired by mixing a nitric acid aqueous solution of 60 mass %, hydrochloric acid of 35 mass %, and pure water at a proportion of 1:1:1 was put in a beaker. When the beaker was heated and the aqueous solution was boiled, the cut laminate 10 was put, and stirring was performed for 3 minutes while maintaining the boiling state. Subsequently, cooling to a room temperature was performed, all the solution in the beaker was moved to a volumetric flask of 100 mL, and the remaining solution adhering in the beaker was further washed with a small amount of pure water three times and also moved to the volumetric flask. Subsequently, pure water was added to set 100 mL. Then, a quantitative analysis of copper, nickel, and phosphorus included in the acquired aqueous solution was performed by using an ICP atomic emission spectroscopy device. A weight (X) of the copper measured by the measurement was 3.084 mg, a weight (Y) of the nickel was 0.271 mg, and a weight (Z) of the phosphorus was 0.024 mg. The acquired weights were substituted in (Y×100)/(X+Y+Z), and the weight of the nickel with respect to a weight of the electroless plating layer 17 was calculated.

### (4) Production of Electrolytic Plating Layer 19

An electrolytic plating solution (top lucina SF made by OKUNO Chemical Industries Co., Ltd.) filled the plating bathtub, and a solution temperature was set to 25° C. The laminate 10 acquired in (3) was immersed in the plating bathtub, and electrolytic plating treatment was performed at 1 A/dm² for 3 minutes and then 2 A/dm² for 26 minutes. In this way, the laminate 20 in which the electrolytic plating layer 19 having a thickness of 12 μm was provided was acquired. Acid resistance and peel strength were evaluated by using the acquired laminate 20.

Note that an evaluation of an insulation resistance value used the laminate in which the electrolytic plating layer 19 having a thickness of 2 μm was provided by immersing the laminate 10 acquired in (3) in the above-described plating bathtub, and 20 performing electrolytic plating treatment at 1 A/dm² for 10 minutes.

A thickness of the electrolytic plating layer 19 of the acquired laminate 20 was measured by using a micrometer.

### Acid Resistance

When an evaluation of acid resistance was performed, a sample was produced by using the laminate 20 in which the electrolytic plating layer 19 had a thickness of 12 μm. First, the laminate 20 cut into a square of 100 mm×100 mm was prepared. Next, a photosensitive dry film was laminated on the electrolytic plating layer 19 of the laminate 20, and bonded by using a vacuum laminator. A condition was 50° C., 0.5 MPa, and 10 seconds, and a degree of vacuum was 3 hPa or less. The photosensitive dry film was a negative dry film, and Sunfort AQ-2075 made by Asahi Kasei Corp. was used.

Next, a surface of the dry film was exposed to light at 80 mJ/cm² via a photomask having a rectangular shape in which an outline of an opening region had a width of 3 mm and a length of 20 mm. Subsequently, an unexposed portion of the dry film was removed by a sodium carbonate aqueous solution (development). The electrolytic plating layer 19 exposed by the development, the electroless plating layer 17 provided under the electrolytic plating layer 19, and the catalyst layer 15 provided under the electroless plating layer 17 were removed. After the removal, the exposed dry film was removed by using a sodium hydroxide aqueous solution. It was confirmed that the electrolytic plating layer 19 exposed after the dry film was removed and the electroless plating layer 17 provided under the electrolytic plating layer 19 were etched in a predetermined rectangular shape when viewed from a direction perpendicular to a main plane of the laminate 20. This was used as a sample. Note that an etching solution used for etching was a ferric chloride solution made by TOAGOSEI CO., LTD.

Next, the acquired sample was heated at 160° C. for 1 hour. The heated sample was immersed in a hydrochloric acid aqueous solution of 10% at 23° C. for 30 minutes, and then washed with water and dried. Subsequently, the electrolytic plating layer 19 and the electroless plating layer 17 provided in the rectangular shape were observed by an optical microscope (VHX-8000 made by KEYENCE CORPORATION). Note that, in the observation, the sample was installed in such a way that a polyimide film surface was disposed on a lens side of the optical microscope. A degree of erosion was checked by using software mounted on VHX-8000. Further, an evaluation was performed by the following criteria.
Good: a depth of erosion of the electrolytic plating layer 19 and the electroless plating layer 17 provided in the rectangular shape was less than 5 μm, and
Poor: a depth of erosion of the electrolytic plating layer 19 and the electroless plating layer 17 provided in the rectangular shape was 5 μm or more.

### Interlayer Adhesiveness

Interlayer adhesiveness of the laminate was evaluated by (i) an evaluation of an adhesion property and (ii) an evaluation of peel strength described below.

### (i) Evaluation of Adhesion Property

An adhesion property between the resin layer 13 and the catalyst layer 15 in the laminate 10 acquired in (3) and an adhesion property between the catalyst layer 15 and the electroless plating layer 17 were observed by visual inspection. Specifically, whether there is peeling between layers of the laminate being cut into a square of 100 mm×100 mm and provided with the electroless plating layer 17, that is, the laminate 10 acquired in (3) production of the electroless plating layer 17 was observed by visual inspection. Further, five laminates were checked for the evaluation and the evaluation was performed by the following criteria.
Good: the number of the laminates in which peeling occurred was less than 2, and
Poor: the number of the laminates in which peeling occurred was 2 or more.

### (ii) Evaluation of Peel Strength

For the laminate 20 acquired in (4), specifically, the laminate 20 in which the electrolytic plating layer 19 had a thickness of 12 μm, peel strength of the electrolytic plating layer 19 before heat treatment and peel strength of the electrolytic plating layer 19 after heat treatment were measured in conformity with JIS C6471.

First, the laminate 20 cut into a square of 100 mm×100 mm was prepared. Next, a photosensitive dry film was laminated on the electrolytic plating layer 19 of the laminate 20, and bonded by using a vacuum laminator. A condition was 50° C., 0.5 MPa, and 10 seconds, and a degree of vacuum was 3 hPa or less. The photosensitive dry film was a negative dry film, and Sunfort AQ-2075 made by Asahi Kasei Corp. was used.

Next, a surface of the dry film was exposed to light at 80 mJ/cm² via a photomask having a rectangular shape in which an outline of an opening region had a width of 3 mm and a length of 20 mm. Subsequently, an unexposed portion of the dry film was removed by a sodium carbonate aqueous solution (development). The electrolytic plating layer 19 exposed by the development, the electroless plating layer 17 provided under the electrolytic plating layer 19, and the catalyst layer 15 provided under the electroless plating layer 17 were removed. After the removal, the exposed dry film was removed by using a sodium hydroxide aqueous solution. It was confirmed that the electrolytic plating layer 19 exposed after the dry film was removed and the electroless plating layer 17 provided under the electrolytic plating layer 19 were etched in a predetermined rectangular shape when viewed from a direction perpendicular to a main plane of the laminate 20. This was used as a sample. Note that an etching solution used for etching was a ferric chloride solution made by TOAGOSEI CO., LTD.

(ii-1) Peel Strength before Heat Treatment

A measurement sample was acquired by bonding a film constituting the acquired sample and a reinforcing plate of stainless steel with a double-sided tape.

(ii-2) Peel Strength after Heat Treatment

The acquired sample was kept under an atmosphere at 150° C. for 240 hours. Subsequently, after the sample was kept at 25° C. and 50 RH % for 24 hours, a measurement sample was acquired by bonding a film constituting the acquired sample and a reinforcing plate of stainless steel with a double-sided tape.

(ii-3) Measurement

Peel strength in a direction at 90° (direction perpendicular to a surface of the measurement sample) was measured in the following measurement condition by using Autograph AGS-500 made by SHIMADZU CORPORATION.

The measurement condition was a condition that a test speed was set to 50 mm/min for copper peel.

Evaluation criteria were as follows.
Excellent: peel strength was 5 N/cm or more,
Good: peel strength was less than 5 N/cm and 3 N/cm or more, and
Poor: peel strength was less than 3 N/cm.

As described above, results of evaluating acid resistance and interlayer adhesiveness of the laminate in Example 1 are shown in Table 1. The laminate in Example 1 indicated excellent acid resistance, and also indicated the results of an excellent adhesion property and excellent peel strength. From this, it has been shown that the laminate in Example 1 had excellent acid resistance and excellent interlayer adhesiveness. Reliability of a circuit of a circuit board using such a laminate was increased.

### Example 2

Production was performed by the same method as the method for producing the laminate in Example 1 except that an electroless plating solution in which a nickel (Ni) concentration was changed to 0.2 g/L was used.

### Example 3

Production was performed by the same method as the method for producing the laminate in Example 1 except that an electroless plating solution in which a nickel (Ni) concentration was changed to 0.34 g/L was used.

### Example 4

Production was performed by the same method as the method for producing the laminate in Example 1 except that a catalytic solution in which the amount of palladium was changed to 0.3 mass % and an electroless plating solution in which a nickel (Ni) concentration was changed to 0.34 g/L were used. Note that it was confirmed that 0.08 mg of the palladium adhered to, per unit area 1 dm², the surface of the resin layer 13 of the laminate acquired in the course of production of a laminate in Example 4.

### Example 5

Production was performed by the same method as the method for producing the laminate in Example 1 except that a catalytic solution in which the amount of palladium was changed to 0.57 mass % and an electroless plating solution in which a nickel (Ni) concentration was changed to 0.34 g/L were used. Note that it was confirmed that 0.2 mg of the palladium adhered to, per unit area 1 dm², the surface of the resin layer 13 of the laminate acquired in the course of production of a laminate in Example 5.

### Example 6

Production was performed by the same method as the method for producing the laminate in Example 1 except that a catalytic solution in which the amount of palladium was changed to 0.15 mass % and an electroless plating solution in which a nickel (Ni) concentration was changed to 0.34 g/L were used. Note that it was confirmed that 0.05 mg of the palladium adhered to, per unit area 1 dm², the surface of the resin layer 13 of the laminate acquired in the course of production of a laminate in Example 6.

### Comparative Example 1

Production was performed by the same method as the method for producing the laminate in Example 1 except that an electroless plating solution in which a nickel (Ni) concentration was changed to 0.1 g/L was used.

### Comparative Example 2

Production was performed by the same method as the method for producing the laminate in Example 1 except that an electroless plating solution in which a nickel (Ni) concentration was changed to 0.44 g/L was used.

A measurement method and an evaluation method of the produced samples in Example 2 to Example 6, Comparative Example 1, and Comparative Example 2 are performed by the same methods as the measurement method and the evaluation method in Example 1.

The evaluation results of the examples and the comparative examples are shown in Table 1 and Table 2. It has been shown from Table 1 that the laminates in Example 2 to Example 6 also had excellent acid resistance and excellent interlayer adhesiveness. Reliability of a circuit of a circuit board using such a laminate was increased.

The laminates in Example 1 to Example 6 included the resin layer 13 including a film that relaxed stress generated when the electroless plating layer 17 was provided and the thermoplastic polyimide resin, and the catalyst layer 15 including palladium as a foundation for further providing the electroless plating layer 17, and thus the laminates conceivably had excellent interlayer adhesiveness. The electroless plating layer 17 including a predetermined amount of nickel had a lot of nickel particularly in the boundary surface of the electroless plating layer 17 in contact with the catalyst layer 15. Thus, even when an acid chemical solution entered the interface between the catalyst layer 15 and the electroless plating layer 17, the electroless plating layer 17 was less likely to be eroded. In other words, the laminate had excellent acid resistance. Reliability of a circuit of a circuit board using such a laminate was increased.

TABLE 1

| | | | | EXAMPLE | EXAMPLE | EXAMPLE | EXAMPLE | EXAMPLE | EXAMPLE |
|---|---|---|---|---|---|---|---|---|---|
| ITEM | | | UNIT | 1 | 2 | 3 | 4 | 5 | 6 |
| CONTENT OF Ni IN ELECTROLESS | | | MASS % | 8.0 | 10.3 | 12.4 | 12.4 | 12.4 | 12.4 |
| PLATING LAYER | | | | | | | | | |
| ACID | | AFTER HEAT | — | Good | Good | Good | Good | Good | Good |
| RESISTANCE | | TREATMENT | | | | | | | |
| ADHESIVE- | ADHESION PROPERTY | | — | Good | Good | Good | Good | Good | Good |
| NESS | PEEL | BEFORE | N/cm | Excellent | Excellent | Excellent | Excellent | Excellent | Excellent |
| | STRENGTH | HEAT | | | | | | | |
| | | TREATMENT | | 7.3 | 7.6 | 7.6 | 7.6 | 7.6 | 7.6 |
| | | AFTER HEAT | N/cm | Excellent | Excellent | Excellent | Excellent | Excellent | Excellent |
| | | TREATMENT | | 7.0 | 7.0 | 7.0 | 7.0 | 7.0 | 7.0 |

TABLE 2

| | | | | COMPARATIVE | COMPARATIVE |
|---|---|---|---|---|---|
| ITEM | | | UNIT | EXAMPLE I | EXAMPLE 2 |
| CONTENT OF Ni IN ELECTROLESS | | | MASS % | 6.6 | 14.0 |
| PLATING LAYER | | | | | |
| ACID RESISTANCE | AFTER HEAT | | — | Poor | Good |
| | TREATMENT | | | | |
| ADHESIVENESS | ADHESION PROPERTY | | — | Good | Poor |
| | PEEL | BEFORE | N/cm | Excellent | Excellent |
| | STRENGTH | HEAT | | 7.0 | 8.0 |
| | | TREATMENT | | | |
| | | AFTER HEAT | N/cm | Excellent | Excellent |
| | | TREATMENT | | 6.8 | 7.5 |

Surface resistivity, an insulation resistance value, and solder heat resistance of the laminates in Example 1 to Example 6 were further evaluated.

### Surface Resistivity

Surface resistivity of the laminate 10 acquired in the production course of the laminate in Example 1 and provided with the electroless plating layer 17 before the electrolytic plating layer 19 was laminated, that is, the laminate 10 acquired in (3) production of the electroless plating layer 17 was measured. With low surface resistivity, when the electrolytic plating layer was provided on the electroless plating layer, a spark in which an unexpected large current flowed, and a burn due to concentration of a current in a portion where a current was more likely to flow and occurrence of scorch were less likely to occur in the electroless plating layer.

### Measurement of Surface Resistivity

The surface resistivity was measured in conformity with JIS K7194. Five points on a surface of the laminate cut into a quadrilateral shape of 80 mm×50 mm were measured with a four point probe by using Loresta-GP MCP-T610 made by Mitsubishi Chemical Corporation. When the surface resistivity was 2.3Ω/□ or less, a spark and a burn were less likely to occur, which was considered to be excellent. The surface resistivity in Example 1 was 0.8Ω/□, and it has been shown that the surface resistivity was excellent.

For the laminates in Example 2 to Example 6, the laminate 10 provided with the electroless plating layer 17 before the electrolytic plating layer 19 was laminated was prepared. A surface resistivity of the laminate in each example was measured by the same method as the method for measuring the surface resistivity of the laminate in Example 1. The surface resistivity in Example 2 was 1.2Ω/□. The surface resistivity in Example 3 was 2.0Ω/□. The surface resistivity in Example 4 was 2.0Ω/□. The surface resistivity in Example 5 was 2.0Ω/□. The surface resistivity in Example 6 was 2.0Ω/□. It has been shown that all of the examples had 2.3Ω/□ or less and excellent surface resistivity.

### Insulation Resistance Value

An insulation resistance value of the laminate 20 acquired in (4) production of the electrolytic plating layer 19 in Example 1, specifically, the laminate 20 in which the electrolytic plating layer having a thickness of 2 μm was provided was measured. When an insulation resistance value between wiring lines provided in the laminate was high, a conductive matter such as copper remaining between the wiring lines in the course of provision of the wiring lines was little, and the conductive matter was able to be reliably removed. A circuit board constituted from such a laminate was less likely to be short-circuited.

### Measurement of Insulation Resistance Value

An insulation resistance value was measured in conformity with JIS C6471. Specifically, the laminate cut into a square of 100 mm×100 mm was prepared. Next, a photosensitive dry film was laminated on the electrolytic plating layer of the laminate, and bonded by using a vacuum laminator. A condition was 50° C., 0.5 MPa, and 10 seconds, and a degree of vacuum was 3 hPa or less. The photosensitive dry film was a negative dry film, and Sunfort AQ-2075 made by Asahi Kasei Corp. was used.

Next, a surface of the dry film was exposed to light at 80 mJ/cm² via a photomask having a pattern corresponding to a shape of an electrode for measuring an insulation resistance value in conformity with JIS C6471. Subsequently, an unexposed portion of the dry film was removed by a sodium carbonate aqueous solution (development). The acquired laminate was immersed in a flash etching aqueous solution for 60 seconds, and the electrolytic plating layer 19 exposed by the development and the electroless plating layer 17 provided under the electrolytic plating layer 19 were removed. Subsequently, the exposed dry film was removed by using a sodium hydroxide aqueous solution. Next, the laminate was immersed in a remover solution 1 (MEC Remover EM-1924 made by MEC COMPANY LTD.) for 10 seconds, and further immersed in a remover solution 2 (MEC Remover CH-1925 made by MEC COMPANY LTD.) for 40 seconds, and the catalyst layer 15 was removed. A measurement sample was acquired through the procedures described above.

An insulation resistance value between measurement electrodes provided in the measurement sample after a direct-current voltage of 500 V was applied for 1 minute by using Digital Ultra High Resistance Meter 5451 made by ADC CORPORATION was measured. When the insulation resistance value was 1.0×10¹²Ω or more, a conductive matter such as copper remaining between wiring lines was little, which was considered to be excellent. The insulation resistance value in Example 1 was 1.0×10¹²Ω or more and was excellent.

Note that the used photomask was produced in conformity with JIS C6471. Further, the used flash etching aqueous solution was an aqueous solution acquired by diluting CPE-800D made by MITSUBISHI GAS CHEMICAL COMPANY, INC. by 5 times.

For the laminates in Example 2 to Example 6, measurement was also performed by the same method as the method for measuring the insulation resistance value of the laminate in Example 1. The insulation resistance value in Example 2 to Example 4 was 1.0×10¹²Ω or more. The insulation resistance value in Example 5 was 1.0×10⁸Ω or less. The insulation resistance value in Example 6 was 1.0×10¹²Ω or more.

As described above, the laminates in Example 2 to Example 4 and Example 6 maintained a high insulation resistance value and were excellent. A circuit board constituted from the laminate was less likely to be short-circuited.

### Solder Heat Resistance

Solder heat resistance of the laminate 20 in which (4) the electrolytic plating layer 19 in Example 1 was provided, specifically, the laminate 20 in which the electrolytic plating layer 19 having a thickness of 12 μm was provided was evaluated.

### Measurement of Solder Heat Resistance

The laminate cut into a square of 30 mm×30 mm was prepared. The laminate was floated in a bath of solder at 340° C. for 60 seconds in such a way that the electrolytic plating layer is in contact with solder. Subsequently, the laminate was raised from the bath of solder, and whether there were a swell and peel was confirmed by visual inspection. The laminate without a swell and peel had excellent solder heat resistance. In the laminate in Example 1, no swell and peel were confirmed, and it has been shown that the laminate had excellent solder heat resistance.

The laminates in Example 2 to Example 6 were also evaluated by the same method as the method for evaluating the solder heat resistance in Example 1. Also, in the laminate in all of the examples, no swell and peel were confirmed, and it has been shown that the laminate had excellent solder heat resistance.

As described above, it has been shown that the laminates in Example 1 to Example 6 had excellent acid resistance and excellent interlayer adhesiveness, and also had low surface resistivity and excellent solder heat resistance. Furthermore, it has been shown that the laminates in Example 1 to Example 4 and Example 6 had a high insulation resistance value. It has been shown that a circuit board that was less likely to be short-circuited by using such a laminate could be provided. Reliability of a circuit of the circuit board using such a laminate was increased.

The foregoing describes some example embodiments for explanatory purposes. Although the foregoing discussion has presented specific embodiments, persons skilled in the art will recognize that changes may be made in form and detail without departing from the broader spirit and scope of the invention. Accordingly, the specification and drawings are to be regarded in an illustrative rather than a restrictive sense. This detailed description, therefore, is not to be taken in a limiting sense, and the scope of the invention is defined only by the included claims, along with the full range of equivalents to which such claims are entitled.

This application claims the benefit of Japanese Patent Application No. 2023-061292, filed on Apr. 5, 2023, the entire disclosure of which is incorporated by reference herein.

### REFERENCE SIGNS LIST

10, 20 Laminate
11 Film
13 Resin layer
15 Catalyst layer
17 Electroless plating layer
19 Electrolytic plating layer

1. A laminate comprising:
a film;
a resin layer including a thermoplastic polyimide resin and being provided on at least one surface of the film;
a catalyst layer including palladium and a dispersant covering the palladium and being provided on the resin layer; and
an electroless plating layer including nickel and copper and being provided on the catalyst layer,
wherein a content of the nickel is 8.0 mass % or more and 13.0 mass % or less with respect to an entire mass of the electroless plating layer.

2. The laminate according to claim 1, wherein the amount of the palladium included in the catalyst layer is 0.05 mg or more and 0.18 mg or less per 1 dm² in a surface of the resin layer.

3. The laminate according to claim 1, further comprising an electrolytic plating layer including copper and being provided on the electroless plating layer.

4. A method for manufacturing a circuit board comprising:
a resist layer provision process of providing a resist layer on the electroless plating layer constituting the laminate according to claim 1;
an exposure process of exposing the resist layer;
a resist pattern provision process of developing the resist layer exposed in the exposure process, and providing a resist pattern corresponding to wiring planned to be provided;
a wiring layer provision process of providing a wiring layer having conductivity on the electroless plating layer exposed after the resist pattern provision process;
a resist pattern removal process of removing the resist pattern;
a flash etching process of removing the electroless plating layer exposed after the resist pattern removal process; and
a catalyst layer removal process of removing the catalyst layer exposed after the flash etching process.

5. A method for manufacturing a circuit board comprising:
an electrolytic plating layer provision process of providing an electrolytic plating layer on the electroless plating layer constituting the laminate according to claim 1;
a resist layer provision process of providing a resist layer on the electrolytic plating layer;
an exposure process of exposing the resist layer;
a resist pattern provision process of developing the resist layer exposed in the exposure process, and providing a resist pattern corresponding to wiring planned to be provided;
a wiring layer provision process of providing a wiring layer having conductivity on the electrolytic plating layer exposed after the resist pattern provision process;
a resist pattern removal process of removing the resist pattern;
a flash etching process of removing the electrolytic plating layer exposed after the resist pattern removal process and the electroless plating layer provided under the electrolytic plating layer; and
a catalyst layer removal process of removing the catalyst layer exposed after the flash etching process.

6. A method for manufacturing a circuit board comprising:
a resist layer provision process of providing a resist layer on the electrolytic plating layer constituting the laminate according to claim 3;
an exposure process of exposing the resist layer;
a resist pattern provision process of developing the resist layer exposed in the exposure process, and providing a resist pattern corresponding to wiring planned to be provided;
a wiring layer provision process of providing a wiring layer having conductivity on the electrolytic plating layer exposed after the resist pattern provision process;
a resist pattern removal process of removing the resist pattern;
a flash etching process of removing the electrolytic plating layer exposed after the resist pattern removal process and the electroless plating layer provided under the electrolytic plating layer; and
a catalyst layer removal process of removing the catalyst layer exposed after the flash etching process.
